(19) United States
(12) Patent Application Publication
(10) Pub. No.: US 2025/0283962 A1
(43) Pub. Date: Sep. 11, 2025

(54) CHEMICAL-SHIFT-ENCODED IMAGING METHOD AND APPARATUS BASED ON PHASE UNWRAPPING, AND DEVICE

(71) Applicant: SHENZHEN INSTITUTES OF ADVANCEDTECHNOLOGY CHINESE ACADEMY OF SCIENCES, Shenzhen (CN)

(72) Inventors: Chao ZOU, Shenzhen (CN); Hairong ZHENG, Shenzhen (CN); Hao PENG, Shenzhen (CN); Chuanli CHENG, Shenzhen (CN); Xin LIU, Shenzhen (CN)

(73) Assignee: SHENZHEN INSTITUTES OF ADVANCEDTECHNOLOGY CHINESE ACADEMY OF SCIENCES, Shenzhen (CN)

(21) Appl. No.: 19/220,553

(22) Filed: May 28, 2025

Related U.S. Application Data
(63) Continuation of application No. PCT/CN2023/133476, filed on Nov. 22, 2023.

(30) Foreign Application Priority Data
Nov. 28, 2022 (CN) 202211512842.6

(51) Int. Cl. G01R 33/48; G01R 33/46; G01R 33/565

(52) U.S. Cl. CPC G01R 33/4828; G01R 33/4625; G01R 33/56527

(57) ABSTRACT

The disclosure discloses a chemical-shift-encoded imaging method and apparatus based on phase unwrapping, and a device. Comprises: performing phase conversion on the phasor candidate solution for the purpose of enabling a difference between a correct solution and an inverse decomposition solution of the phasor candidate solution to be within a set range, and on the basis of a phase unwrapping method, performing determination to obtain an intermediate phasor solution; determining a true phase of the intermediate phasor solution, and converting the true phase to a phasor candidate solution space to determine a target phasor solution; and on the basis of the target phasor solution, determining a first chemical component signal and a second chemical component signal, and on the basis of the first chemical component signal and/or the second chemical component signal, performing chemical-shift-encoded imaging.

### CROSS-REFERENCE TO RELATED APPLICATIONS

The application claims priority to Chinese patent application No. 202211512842.6, filed on Nov. 28, 2022, the entire contents of which are incorporated herein by reference.

### TECHNICAL FIELD

The present disclosure relates to the technical field of image processing, and in particular to a chemical-shift-encoded imaging method and apparatus based on phase unwrapping, and a device.

### BACKGROUND

Magnetic resonance chemical-shift-encoded imaging can resolve the relative contents of different components in a detected object by detecting their resonance frequency differences, with water-fat separation imaging being a prime example. The most crucial aspect of water-fat separation is solving of the field, i.e., how to select a suitable solution among a plurality of possible candidate solutions.

In the process of implementing the present disclosure, it has been discovered that at least the following technical problems exist in the existing technologies: the current water-fat separation methods often rely on specific initial information to address the water-fat separation problem, such as the region-growing method based on seed points and the transition region extraction method based on water-fat transition regions, which require the acquired images to meet specific conditions. However, when the acquisition parameters do not satisfy these specific conditions, the original assumptions of the algorithms are undermined and there is a lack of sufficient initial information, resulting in algorithm instability and, consequently, poor performance in chemical-shift-encoded imaging.

### SUMMARY

The present disclosure provides a chemical-shift-encoded imaging method and apparatus based on phase unwrapping, and a device, to solve the technical problem of poor stability and low accuracy in chemical shift component separation when the acquisition parameters do not meet specific conditions. The present disclosure ensures the stability and accuracy of chemical shift component separation under the condition that acquisition parameters do not satisfy specific conditions, thereby improving the chemical-shift-encoded imaging effect.

According to an aspect of the present disclosure, there is provided a chemical-shift-encoded imaging method based on phase unwrapping, including:
acquiring an initial image, and determining phasor candidate solutions of the initial image;
performing phase conversion on the phasor candidate solutions for the purpose of enabling a difference between a correct solution and an inverse decomposition solution of the phasor candidate solutions to be within a set range, and on the basis of a phase unwrapping method, performing determination to obtain an intermediate phasor solution;
determining a true phase of the intermediate phasor solution, and converting the true phase to a phasor candidate solution space to determine a target phasor solution; and
on the basis of the target phasor solution, determining a first chemical component signal and a second chemical component signal, and on the basis of the first chemical component signal and/or the second chemical component signal, performing chemical-shift-encoded imaging.

Optionally, further, performing phase conversion on the phasor candidate solutions for the purpose of enabling the difference between the correct solution and the inverse decomposition solution of the phasor candidate solutions to be within the set range includes:
determining an intermediate variable corresponding to the correct solution and the inverse decomposition solution; and
performing phase conversion on the phasor candidate solutions based on a variable parameter of the intermediate variable such that a phase difference between the phasor candidate solutions is within a set range.

Optionally, further, on the basis of the phase unwrapping method, performing determination to obtain the intermediate phasor solution includes:
performing phase unwrapping on the intermediate variable to obtain a first unwrapped phase; and
matching the first unwrapped phase with an original phase candidate solution to obtain the intermediate phasor solution based on a matching result.

Optionally, further, determining the true phase of the intermediate phasor solution includes:
for a pixel point in the intermediate phasor solution, matching phasor information of the pixel point in the intermediate phasor solution with an original phasor candidate solution, determining target phasor information of the pixel point according to a matching result; and
determining the true phase according to the target phasor information of each pixel point.

Optionally, further, matching the phasor information of the pixel point in the intermediate phasor solution with the original phasor candidate solution includes:
matching phasor information of the pixel point in the intermediate phasor solution with an original phasor candidate solution by Cost(r)=min(|P_{w}(r)−Pₜₙ(r)|, |Pr(r)−Pₜₙ(r)|), wherein Pₜ is the phasor information of the pixel point in the intermediate phasor solution, Pₜₙ is the original phasor candidate solution, and r is the spatial position of the pixel point.

Optionally, further, the method further includes:
when phase wrapping exists in the phasor candidate solutions, performing phase unwrapping on the phasor candidate solutions by a second intermediate variable to obtain a second unwrapped phase; and
performing phase compression on the second unwrapped phase to compress the second unwrapped phase within a set range.

Optionally, further, the first chemical component is water and the second chemical component is fat.

According to another aspect of the present disclosure, there is provided chemical-shift-encoded imaging apparatus based on phase unwrapping, including:
a phasor candidate solution determining module, configured to acquire an initial image, and determine phasor candidate solutions of the initial image;
an intermediate phasor solution determining module, configured to perform phase conversion on the phasor candidate solutions for the purpose of enabling a difference between a correct solution and an inverse decomposition solution of the phasor candidate solutions to be within a set range, and on the basis of a phase unwrapping method, perform determination to obtain an intermediate phasor solution;
a target phasor solution determining module, configured to determine a true phase of the intermediate phasor solution, and convert the true phase to a phasor candidate solution space to determine a target phasor solution; and
a chemical-shift-encoded imaging module, configured to, on the basis of the target phasor solution, determine a first chemical component signal and a second chemical component signal, and on the basis of the first chemical component signal and/or the second chemical component signal, perform chemical-shift-encoded imaging.

According to another aspect of the present disclosure, there is provided an electronic device, including:
at least one processor; and
a memory communicatively connected with the at least one processor; wherein,
the memory stores a computer program executable by the at least one processor, the computer program being executed by the at least one processor to enable the at least one processor to perform the chemical-shift-encoded imaging method based on phase unwrapping according to any one of the embodiments of the present disclosure.

According to another aspect of the present disclosure, there is provided a computer-readable storage medium having stored thereon computer instructions for causing a processor to implement the chemical-shift-encoded imaging method based on phase unwrapping according to any one of the embodiments of the present disclosure.

The technical solution of an embodiment of the present disclosure is as follows: acquiring an initial image, and determining a phasor candidate solution of the initial image; performing phase conversion on the phasor candidate solution for the purpose of enabling a difference between a correct solution and an inverse decomposition solution of the phasor candidate solution to be within a set range, and on the basis of a phase unwrapping method, performing determination to obtain an intermediate phasor solution; determining a true phase of the intermediate phasor solution, and converting the true phase to a phasor candidate solution space to determine a target phasor solution; and on the basis of the target phasor solution, determining a first chemical component signal and a second chemical component signal, and on the basis of the first chemical component signal and/or the second chemical component signal, performing chemical-shift-encoded imaging. By transforming the phase difference between the phasor candidate solutions to fall within a set range, the problem of selecting one of two phasors in different chemical components is converted into a phase unwrapping problem, which can then be resolved using the phase unwrapping technology.

It should be understood that what is described in this section is not intended to identify key or critical features of embodiments of the disclosure, nor is it intended to limit the scope of the disclosure. Other features of the present disclosure will become apparent from the following description.

### BRIEF DESCRIPTION OF DRAWINGS

To illustrate the technical solutions in the embodiments of the present disclosure more clearly, the accompanying drawings required for use in the description of the embodiments will be briefly described below, and it is obvious that the accompanying drawings in the following description are only some embodiments of the present disclosure, and other drawings can be obtained from these drawings for those skilled in the art without inventive step.

FIG. 1 is a flowchart of a chemical-shift-encoded imaging method based on phase unwrapping according to Embodiment One of the present disclosure;

FIG. 2 is a flowchart of a chemical-shift-encoded imaging method based on phase unwrapping according to Embodiment Two of the present disclosure;

FIG. 3 is a schematic diagram of a process for performing phase inversion through an intermediate variable according to Embodiment Two of the present disclosure;

FIG. 4 is a schematic diagram of phase wrapping processing of phasor candidate solutions according to Embodiment Two of the present disclosure;

FIG. 5 is a structural schematic diagram of a chemical-shift-encoded imaging apparatus based on phase unwrapping according to Embodiment Three of the present disclosure; and

FIG. 6 is a structural schematic diagram of an electronic device according to Embodiment Four of the present disclosure.

### DETAILED DESCRIPTION OF THE EMBODIMENTS

In order for those skilled in the art to better understand the present solutions, the technical solutions in the embodiments of the present disclosure will be clearly and completely described below in conjunction with the accompanying drawings in the embodiments of the present disclosure, it is obvious that the described embodiments are only a part of embodiments of the present disclosure, rather than all of the embodiments. Based on the embodiments in the present disclosure, all other embodiments obtained by those of ordinary skill in the art without making inventive labor should belong to the scope of protection of the present disclosure.

It should be noted that the terms “first” and “second” and the like in the description and claims of the present disclosure and the figures above are used for distinguishing between similar objects and not necessarily for describing a particular sequential or chronological order. It should be understood that the data so used may be interchangeable where appropriate so that the embodiments of the disclosure described herein can be practiced in an order other than those illustrated or described herein. Furthermore, the terms “including” and “having” and any variations thereof are intended to cover a non-exclusive inclusion, for example, a process, method, system, product, or device including a series of steps or units is not necessarily limited to those steps or units clearly listed, but may include other steps or units not clearly listed or inherent to such processes, methods, products, or devices.

### Embodiment One

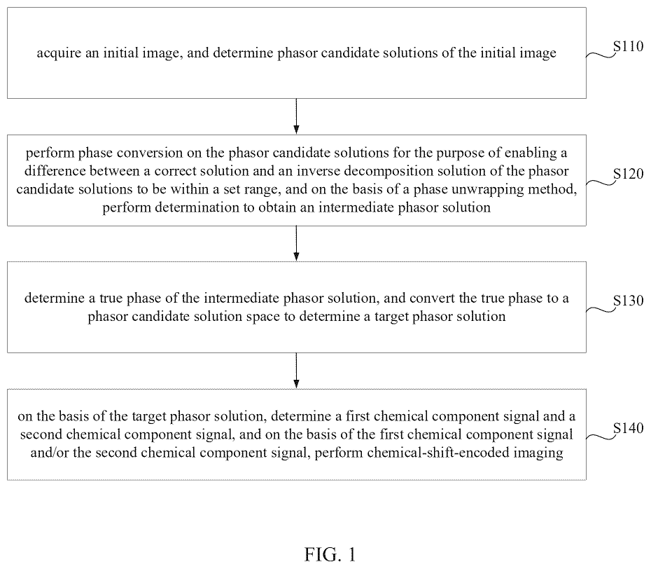

FIG. 1 is a flowchart of a chemical-shift-encoded imaging method based on phase unwrapping according to Embodiment One of the present disclosure. This embodiment is applicable to scenarios where chemical shift components need to be separated for chemical-shift-encoded imaging, particularly in situations where the acquired information does not meet specific conditions. The method can be executed by a chemical-shift-encoded imaging apparatus based on phase unwrapping, which can be implemented in hardware and/or software forms. This chemical-shift-encoded imaging apparatus based on phase unwrapping can be configured within an electronic device. As shown in FIG. 1, the method includes:

S110, an initial image is acquired, and phasor candidate solutions of the initial image are determined.

In this embodiment, chemical-shift-encoded imaging is performed based on an initial image. Optionally, the initial image can be reconstructed from magnetic resonance signals acquired using a magnetic resonance imaging method. It should be noted that this embodiment enables chemical-shift-encoded imaging even when the initial information is uncertain. Therefore, there are no restrictions on the method used to acquire the initial image or on the parameters of the acquisition equipment (such as magnetic field strength, acquisition bandwidth, etc.). It is possible to stably separate signals of different chemical components even when the initial information in the initial image reconstructed from the acquired signals is uncertain.

In one implementation, the phasor candidate solutions of the initial image may be calculated by a transition region extraction method or a seed point identification method.

Optionally, the step that the phasor candidate solutions of the initial image are determined includes: for each pixel point, a fitting error of the pixel point is determined; a phasor of the fitting error corresponding to a local minimum is taken as the phasor candidate solution. Taking chemical-shift-encoded imaging using water-fat signal separation as an example, for each pixel point, the fitting error of the pixel point can be determined according to err (p)=|S−A(p)A⁺(p)S∥₂², wherein err (p) is the fitting error, S is the acquired water-fat signal, p is the phasor, and A is a parameter matrix of a multi-point Dixon signal model. The local minimum of err (p) can be sought by traversing (−π, π] according to the above equation, and a phasor of the fitting error corresponding to the local minimum is taken as the phasor candidate solution of the pixel point.

In some embodiments, prior to performing phase conversion on the phasor candidate solutions for the purpose of enabling the difference between the correct solution and the inverse decomposition solution of the phasor candidate solutions to be within the set range, the method further includes: when phase wrapping exists in the phasor candidate solutions, phase unwrapping is performed on the phasor candidate solutions by a second intermediate variable to obtain a second unwrapped phase; and phase compression is performed on the second unwrapped phase to compress the second unwrapped phase within a set range.

Considering the existence of phase wrapping in the correct solution or the inverse decomposition solution of the phasor in practical scenarios, when one of the candidate solutions undergoes a phase wrapping change of 2π while the other does not, phase unwrapping can first be performed on the candidate solutions (such as P_{nw} or P_{nf}) of the phasor to obtain the corresponding second unwrapped phases UPw and Upf. Subsequently, these second unwrapped phases are compressed into the range of [−π, π], thereby simplifying the problem to a situation where the candidate solutions have no phase wrapping. After this processing, subsequent operations for chemical-shift-encoded imaging can be directly carried out.

S120, phase conversion is performed on the phasor candidate solutions for the purpose of enabling a difference between a correct solution and an inverse decomposition solution of the phasor candidate solutions to be within a set range, and on the basis of a phase unwrapping method, determination is performed to obtain an intermediate phasor solution.

Overall, this embodiment converts the problem of selecting one of two phasors in different chemical components into a phase unwrapping problem, which is solved in combination with existing phase unwrapping techniques.

In one implementation of the present disclosure, the step that phase conversion is performed on the phasor candidate solutions for the purpose of enabling a difference between a correct solution and an inverse decomposition solution of the phasor candidate solutions to be within a set range includes:
an intermediate variable corresponding to the correct solution and the inverse decomposition solution is determined; and
phase conversion is performed on the phasor candidate solutions based on a variable parameter of the intermediate variable such that a phase difference between the phasor candidate solutions is within a set range.

Optionally, the phase difference between the phasor candidate solutions can be transformed into 2π by utilizing an intermediate variable, so as to converts the problem of selecting one of two phasors in different chemical components into a phase unwrapping problem.

First, for the correct solution and the inverse decomposition solution of the phasor, the following intermediate variable can be defined:

Pₘ=p\hat{ }m

Thus, according to Equation (6), the intermediate variable can be expressed as:

$${P}_{m} \{ \begin{matrix}{P}_{t} \hat{} m & p = {P}_{t} \\ {P}_{t} \hat{} m \cdot {e}^{- im \cdot 2 π {f}_{F} Δ TE} & {ρ}_{w} ≫ {ρ}_{f} , p = {P}_{a} \\ {P}_{t} \hat{} m \cdot {e}^{- im \cdot 2 π {f}_{F} Δ TE} & {ρ}_{w} ≪ {ρ}_{f} , p = {P}_{a}\end{matrix}$$

When a transformation coefficient m=1/f_{F}ΔTE is selected, e^{im·2πf}^{_{F}}^{ΔTE}=1, i.e., the correct and erroneous solutions of the phasor are unified. Based on this, phase conversion can be performed on the phasor candidate solutions by the variable parameter of the intermediate variable such that the phase difference between the phasor candidate solutions is within a set range.

In one implementation, the step that, on the basis of the phase unwrapping method, determination is performed to obtain the intermediate phasor solution includes:
phase unwrapping is performed on the intermediate variable to obtain a first unwrapped phase; and
the first unwrapped phase is matched with an original phase candidate solution to obtain the intermediate phasor solution based on a matching result.

Optionally, assuming that phase unwrapping is performed on the intermediate variable Pₘ, and the resulting phase is denoted as UP, then, an overall smooth phase can be obtained. However, when using this phase to calculate the original phasor, the difference between m∠Pₜ and UP may be an integer multiple of 2π. The mismatch problem between m∠Pₜ and UP is relatively simple and can be resolved by matching with the original phasor candidate solution. The possible candidate solution of the phasor can be denoted as Pₜₙ:

$${P}_{tn} = {e}^{i \frac{1}{m} ( UP + 2 n π )}$$

Then the choice of n in the above equation can be determined by a matching equation as follows:

$$C ( n ) = {\sum }_{r} min ( \vert {P}_{w} ( r ) - {P}_{tn} ( r ) \vert , \vert {P}_{f} ( r ) - {P}_{tn} ( r ) \vert )$$

Wherein, r is the spatial position of all pixel points and Pₜₙ with the smallest cost function is the correct solution of the phasor, i.e., the intermediate phasor solution.

S130, a true phase of the intermediate phasor solution is determined, and the true phase is converted to a phasor candidate solution space to determine a target phasor solution.

In this embodiment, after the intermediate phasor solution is determined, the true phase of the intermediate phasor solution needs to be converted to the phasor candidate solution space to obtain the target phasor solution.

In one implementation of the disclosure, the step that the true phase of the intermediate phasor solution is determined includes: for a pixel point in the intermediate phasor solution, phasor information of the pixel point in the intermediate phasor solution is matched with an original phasor candidate solution, target phasor information of the pixel point is determined according to a matching result; and the true phase is determined according to the target phasor information of each pixel point.

Optionally, the step that the phasor information of the pixel point in the intermediate phasor solution is matched with an original phasor candidate solution includes:

the phasor information of the pixel point in the intermediate phasor solution is matched with the original phasor candidate solution by Cost(r)=min(|P_{w}(r)−Pₜₙ(r)|, |P_{f}(r)−Pₜₙ(r)|), wherein Pₜ is the phasor information of the pixel point in the intermediate phasor solution, Pₜₙ is the original phasor candidate solution, and r is the spatial position of the pixel point.

The correctness of the obtained phasor solution can be verified pixel point by pixel point using the aforementioned equation. The parts with errors in the unwrapping process will show a relatively large difference from the original phasor candidate solutions. For those cases where the calculated cost function is greater than 0.1, the phasor solution can be marked as pending and recalculated through spatial filtering. Through this process, a self-verification mechanism for the phasor can be established to ensure its accuracy.

S140, on the basis of the target phasor solution, a first chemical component signal and a second chemical component signal are determined, and on the basis of the first chemical component signal and/or the second chemical component signal, chemical-shift-encoded imaging is performed.

In this embodiment, after an accurate target phasor solution is obtained, the separated first chemical component signal and second chemical component signal can be directly calculated based on the target phasor solution. Subsequently, the chemical-shift-encoded imaging result of the first chemical component can be obtained and displayed based on the first chemical component signal. And/or, the chemical-shift-encoded imaging result of the second chemical component can be obtained and displayed based on the second chemical component signal.

Optionally, the first chemical component is water and the second chemical component is fat. Accordingly, the first chemical component signal is a water signal and the second chemical component signal is a fat signal, and the target water signal and the target fat signal may be separated via [ρ_{w}, ρ_{f}]^{T}=ϕ⁺(ψ)S, wherein ρ_{w} is the target water signal, ρ_{f} is the target fat signal, ψ is the inhomogeneity of the main magnetic field, and Φ(ψ) is a function of ψ. After separating out the target water signal and the target fat signal, a water signal image may be generated based on the target water signal, a fat signal image may be generated based on the target fat signal, and the water signal image and the fat signal image may be displayed.

The technical solution of this embodiment is as follows: acquiring an initial image and determining an initial phasor solution of a conversion region based on the initial image; using the initial phasor solution as initial information, performing local phasor iteration along at least two predetermined directions, and obtaining a target phasor solution based on the local phasor iteration result corresponding to each predetermined direction; determining a first chemical component signal and a second chemical component signal based on the target phasor solution, and performing chemical-shift-encoded-imaging based on the first chemical component signal and/or the second chemical component signal. By conducting local phasor iterations across multiple dimensions, erroneous phasor information is independently propagated along different dimensions. The results of these multi-dimensional local phasor iterations are then merged to exclude the erroneous information propagated along different directions while preserving consistent and correct information across all dimensions. This method resolves the technical problem of difficulty in accurately obtaining phasor information under conditions of uncertain initial information, which can result in poor stability and low accuracy of the separated chemical component signals. In the case where the initial information is uncertain, the separated chemical component signal is more accurate, and the chemical-shift-encoded imaging effect is improved.

### Embodiment Two

The present embodiment provides a preferred embodiment on the basis of the above embodiment.

In the embodiments of the present disclosure, taking chemical-shift-encoded imaging using water-fat signal separation as an example, a method for determining the correct solution of the phasor by incorporating the phase unwrapping technology is proposed. This method enables accurate acquisition of phasor information even when the acquired information does not meet specific conditions, thereby addressing the problem of insufficient stability in water-fat separation under such circumstances.

In general, the original candidate solutions are first subjected to phase conversion, such that the difference between the correct solution and the inverse decomposition solution of the phasor becomes 2π. Subsequently, the phase unwrapping method is employed to determine the true phase, which is then converted to the original candidate solution space to determine the correct solution of the phasor. After obtaining the correct solution of the phasor, the respective contents of water and fat are calculated through matrix inversion, followed by chemical-shift-encoded imaging.

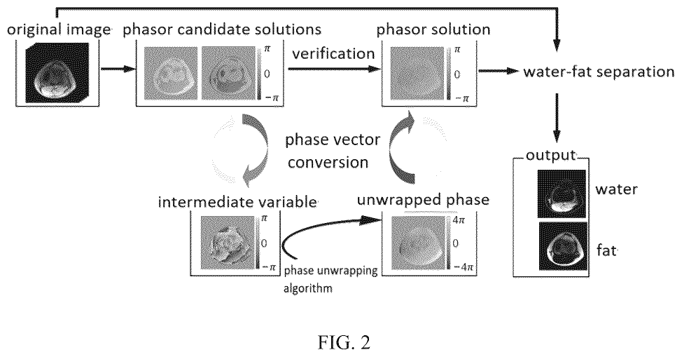

FIG. 2 is a flowchart of a chemical-shift-encoded imaging method based on phase unwrapping according to Embodiment Two of the present disclosure. With reference to FIG. 2, specific steps include:

in a multi-echo gradient echo sequence, when factors such as the multi-peak characteristic of fat and transverse relaxation decay are neglected, a simplified model for water-fat separation can be expressed as follows.

$${S}_{n} = ( {ρ}_{w} + {ρ}_{f} {e}^{i 2 π {f}_{F} {TE}_{n}} ) {w}^{- i 2 πψ {TE}_{n}} \qquad ( 1 )$$

Wherein, ρ_{w} and ρ_{f} are the contents of water and fat, respectively; f_{F} is the resonance frequency difference between fat and water, typically 3.4 ppm; TEₙ is the echo time; and ψ represents the inhomogeneity of the main magnetic field.

The above equation is rewritten into a matrix form as follows:

$$S = Φ ( ψ ) ρ \qquad ( 2 )$$

Wherein, ρ=[ρ_{w}>ρ_{f}]^{T}, and Φ(ψ) is a function of ψ:

$$Φ ( ψ ) = [ \begin{matrix}{e}^{- i 2 πϕ {TE}_{1}} & {e}^{- i 2 π ( ϕ + {f}_{F} ) {TE}_{1}} \\ {e}^{- i 2 πϕ {TE}_{2}} & {e}^{- i 2 π ( ϕ + {f}_{F} ) {TE}_{2}} \\ ⋯ & ⋯ \\ {e}^{- i 2 πϕ {TE}_{n}} & {e}^{- i 2 π ( ϕ + {f}_{F} ) {TE}_{n}}\end{matrix} ] \qquad ( 3 )$$

According to VARPRO, the field ψ can be used to uniquely represent the water and fat signals, that is:

$$ρ = {Φ}^{+} ( ψ ) S \qquad ( 4 )$$

Thus, through the above steps, the key in the water-fat separation problem falls to the solving of the phasor. To avoid the problem of phase wrapping, document introduces the concept of phasor:

p=e^{i2πΔTE} (5)

The main magnetic field inhomogeneity can be equivalently expressed using the phasor p. Since the phasor is fixed in magnitude, it only needs to traverse over the range of [−π, π] to find candidate solutions of the phasor:

$$p = arg {min}_{p} {‖ S - Ψ ( p ) {Ψ}^{+} ( p ) S ‖}_{2}^{2} \qquad ( 6 )$$

The difference between the phasor candidate solutions has been described in the document. For both multi-point water-fat separation and two-point water-fat separation, the following equation can be obtained:

$$∠ p = \{ \begin{matrix}∠ {P}_{t} & p = {P}_{t} \\ ∠ {P}_{t} {e}^{i 2 π {f}_{F} Δ TE} & {ρ}_{w} ≫ {ρ}_{f} , p = {P}_{a} \\ ∠ {P}_{t} {e}^{- i 2 π {f}_{F} Δ TE} & {ρ}_{w} ≪ {ρ}_{f} , p = {P}_{a}\end{matrix} \qquad ( 7 )$$

Wherein Pₜ is the correct solution of the phasor and Pₐ is the inverse decomposition solution of the phasor. A solution in the phasor candidate solutions with a higher calculated water component is denoted as P_{w}, and one with a higher fat component is denoted as P_{f}. This disclosure addresses the water-fat separation problem by transforming it into a phase unwrapping problem and integrating existing phase unwrapping algorithms.

First, for the correct solution and the inverse decomposition solution of the phasor, the following intermediate variable can be defined as a first intermediate variable:

$${P}_{m} = p \hat{} m \qquad ( 8 )$$

Thus, according to Equation (6), the intermediate variable can be expressed as:

$${P}_{m} = \{ \begin{matrix}{P}_{t} \hat{} m & p = {P}_{t} \\ {P}_{t} \hat{} m \cdot {e}^{im \cdot 2 π {f}_{F} Δ TE} & {ρ}_{w} ≫ {ρ}_{f} , p = {P}_{a} \\ {P}_{t} \hat{} m \cdot {e}^{- im \cdot 2 π {f}_{F} Δ TE} & {ρ}_{w} ≪ {ρ}_{f} , p = {P}_{a}\end{matrix} \qquad ( 9 )$$

When a transformation coefficient m=1/f_{F}ΔTE is selected, e^{im·2πf}^{_{F}}^{ΔTE}=1 i.e., the correct and erroneous solutions of the phasor are unified.

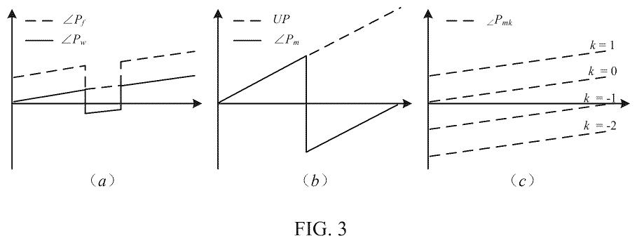

FIG. 3 is a schematic diagram of a process for performing phase inversion through an intermediate variable according to Embodiment Two of the present disclosure. As shown in FIG. 3, by introducing an intermediate variable Pm, the difference between the correct and erroneous solutions of the phasor is eliminated, thereby resolving the water-fat ambiguity problem through phase unwrapping and candidate solution matching.

Assuming that, at this point, ∠pₜ+2πf_{F}ΔTE, ∠pₜ−2πf_{F}ΔTE and m∠pₜ are all within the range of [−π, π], m∠pₜ=∠Pₘ can be obtained, i.e., the correct solution of the phasor: wherein Pₜ is the correct solution of the phasor and Pₐ is the inverse decomposition solution of the phasor.

$${P}_{t} = {e}^{i \frac{1}{m} ∠ {P}_{m}} \qquad ( 10 )$$

However, since the phase of Pₜ is magnified by a factor of m, when m∠pₜ exceeds the range of [−π, π], ∠Pₘ is the value of m∠pₜ wrapped into the range of [−π, π], that is:

$$∠ {P}_{m} = m ∠ {P}_{t} + 2 k π \qquad ( 11 )$$

By performing phase unwrapping on the intermediate variable Pₘ and denoting the resulting phase as UP, an overall smooth phase can be obtained. However, when using this phase to calculate the original phasor, the difference between m∠Pₜ and UP is an integer multiple of 2π. The mismatch problem between m∠Pₜ and UP is relatively simple, and can be resolved by matching with the original phasor candidate solution. The possible candidate solution of the phasor can be denoted as Pₜₙ:

$${P}_{tn} = {e}^{i \frac{1}{m} ( UP + 2 n π )} \qquad ( 12 )$$

Then the choice of n in the above equation can be determined by a matching equation as follows:

$$C ( n ) = {\sum }_{r} min ( \vert {P}_{w} ( r ) - {P}_{tn} ( r ) \vert , \vert {P}_{f} ( r ) - {P}_{tn} ( r ) \vert ) \qquad ( 13 )$$

Wherein, r is the spatial position of all pixel points and Pₜₙ with the smallest cost function is the correct solution of the phasor. The coefficient n corresponding to the minimum cost function is denoted as N, then, the real phasor solution is as follows:

$${P}_{tn} = {e}^{i \frac{1}{m} ( UP + 2 N π )} \qquad ( 14 )$$

Finally, after computing the phasor solution Pₜ, Pₜ of each pixel point is matched with the phasor candidate solution:

$$Cost ( r ) = min ( \vert {P}_{w} ( r ) - {P}_{tn} ( r ) \vert , \vert {P}_{f} ( r ) - {P}_{tn} ( r ) \vert ) \qquad ( 15 )$$

The difference between Equation (15) and Equation (13) lies in that Equation (13) is computed for the entire image, the unwrapped result is matched with the original phasor candidate solution to determine their relative relationship; whereas Equation (15) is applied to each pixel point individually to verify the correctness of the obtained phasor solution. The erroneous part of the unwrapping process will differ significantly from the original phasor candidate solution. For those pixel points where the cost function calculated by Equation (15) is greater than 0.1, the phasor solution is marked as pending and recalculated using spatial filtering. This process forms a self-verification mechanism for the phasor.

However, in practice, it is also possible that there is phase wrapping in the correct solution or the inverse decomposition solution of the phasor. When one of the candidate solutions undergoes a phase wrapping change of 2π while the other does not, the phase difference between the candidate solutions changes from the original 2πf_{F}ΔTE to 2π−2πf_{F}ΔTE. The phase wrapping of 2π can further cause abrupt changes in the intermediate variable Pₘ:

$$Δγ = 2 π \cdot m - 2 k π \qquad ( 16 )$$

The range of Δγ is [−π, π]. When ΔTE=1.5 ms, and m=1.54, then the corresponding phase abrupt change is Δγ=−0.92π. For this phenomenon, the candidate solutions of the phasor P_{w} and P_{f} may first be phase unwrapped, resulting in UPw and UPf. The unwrapped phase is then compressed to within a range of [−π, π], thereby simplifying the problem to a scenario where the candidate solutions do not have phase wrapping, and the method described earlier can be used to solve it. Second intermediate variables P_{nw} and P_{nf} are established, which have a one-to-one correspondence with UPw and UPf, respectively:

$$\begin{matrix}{P}_{nw} = {e}^{i * ( UPw - lb ) / {m}_{2}} \\ {P}_{nf} = {e}^{i * ( UPf - lb ) / {m}_{2}}\end{matrix} \qquad ( 17 )$$

Wherein, m₂ is the proportional relationship between the range of variation of UPw and UPf and 2π, that is:

$${m}_{2} = ( ub / lb ) / 2 \qquad ( 18 )$$

ub and lb are the upper and lower bounds of the union of UPw and UPf, respectively. During this process, the phase difference between the correct solution and the inverse decomposition solution of the phasor becomes 2πf_{F}ΔTE/m₂. Consequently, when calculating the intermediate variable Pₘ, the coefficient m is m∠/f_{F}ΔTE instead of 1/f_{F}ΔTE. All other steps remain exactly the same as previously described.

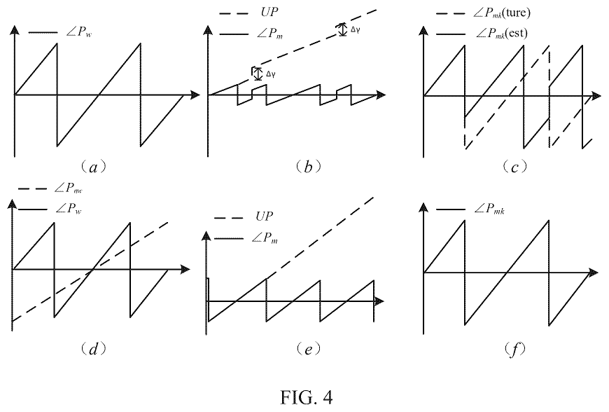

FIG. 4 is a schematic diagram of phase wrapping processing of phasor candidate solutions according to Embodiment Two of the present disclosure. In FIG. 4, (a-c) shows the resulting deviation of the estimated phasor when phase wrapping of the phasor candidate solutions occurs; (d-f) shows that his problem is avoided by constructing the second intermediate variables Pnw and Pnf to compress the original phase into the range of [−π, π].

After the correct phasor solution is obtained, the contents of water and fat can be calculated by Equation (4).

On the basis of the above embodiment, the signal model in Equation (1) can be modified so that the method performed on the basis of the modified signal model can be used for other chemical-shift-encoded imaging methods corresponding to chemical shift components.

An embodiment of the present disclosure provides a phasor conversion method to convert the original water-fat ambiguity problem into a phase unwrapping problem, and determine the correct phasor by means of phasor matching. The phase difference between the phasor candidate solutions is transformed into 2π by establishing the intermediate variables, thereby converting the problem of selecting one of two phasors in water-fat ambiguity into a phase unwrapping problem, which can be resolved using existing phase unwrapping techniques. The unwrapped phase is then matched with the original phase candidate solutions to determine the specific value of 2Nπ by which the unwrapped phase differs from the true phase. The calculated phasor is matched with the original phase candidate solutions to form a self-verification mechanism for the phasor. When phase wrapping exists in the candidate solutions, the second intermediate variables are established to compress the original phase into the range of [−π, π], thereby transforming the problem into a scenario that can be handled by the method described in the patent.

### Embodiment Three

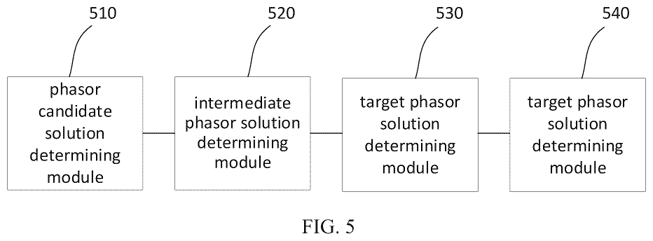

FIG. 5 is a structural schematic diagram of a chemical-shift-encoded imaging apparatus based on phase unwrapping according to Embodiment Three of the present disclosure. As shown in FIG. 5, the apparatus includes a phasor candidate solution determining module 510, an intermediate phasor solution determining module 520, a target phasor solution determining module 530 and a chemical-shift-encoded imaging module 540, wherein:
a phasor candidate solution determining module 510 is configured to acquire an initial image, and determine phasor candidate solutions of the initial image;
an intermediate phasor solution determining module 520 is configured to perform phase conversion on the phasor candidate solutions for the purpose of enabling a difference between a correct solution and an inverse decomposition solution of the phasor candidate solutions to be within a set range, and on the basis of a phase unwrapping method, perform determination to obtain an intermediate phasor solution;
a target phasor solution determining module 530 is configured to determine a true phase of the intermediate phasor solution, and convert the true phase to a phasor candidate solution space to determine a target phasor solution; and
a chemical-shift-encoded imaging module 540 is configured to, on the basis of the target phasor solution, determine a first chemical component signal and a second chemical component signal, and on the basis of the first chemical component signal and/or the second chemical component signal, perform chemical-shift-encoded imaging.

The technical solution of this embodiment is as follows: acquiring an initial image and determining an initial phasor solution of a conversion region based on the initial image; using the initial phasor solution as initial information, performing local phasor iteration along at least two predetermined directions, and obtaining a target phasor solution based on the local phasor iteration result corresponding to each predetermined direction; determining a first chemical component signal and a second chemical component signal based on the target phasor solution, and performing chemical-shift-encoded-imaging based on the first chemical component signal and/or the second chemical component signal. By conducting local phasor iterations across multiple dimensions, erroneous phasor information is independently propagated along different dimensions. The results of these multi-dimensional local phasor iterations are then merged to exclude the erroneous information propagated along different directions while preserving consistent and correct information across all dimensions. This method resolves the technical problem of difficulty in accurately obtaining phasor information under conditions of uncertain initial information, which can result in poor stability and low accuracy of the separated chemical component signals. In the case where the initial information is uncertain, the separated chemical component signal is more accurate, and the chemical-shift-encoded imaging effect is improved.

On the basis of the above embodiment, optionally, the intermediate phasor solution determining module 520 is specifically configured to:
determine an intermediate variable corresponding to the correct solution and the inverse decomposition solution; and
perform phase conversion on the phasor candidate solutions based on a variable parameter of the intermediate variable such that a phase difference between the phasor candidate solutions is within a set range.

On the basis of the above embodiment, optionally, the intermediate phasor solution determining module 520 is specifically configured to:
perform phase unwrapping on the intermediate variable to obtain a first unwrapped phase; and
match the first unwrapped phase with an original phase candidate solution to obtain the intermediate phasor solution based on a matching result.

On the basis of the above embodiment, optionally, the target phasor solution determining module 530 is specifically configured to:
for a pixel point in the intermediate phasor solution, match phasor information of the pixel point in the intermediate phasor solution with an original phasor candidate solution, determine target phasor information of the pixel point according to a matching result; and
determine the true phase according to the target phasor information of each pixel point.

On the basis of the above embodiment, optionally, the target phasor solution determining module 530 is specifically configured to:
match phasor information of the pixel point in the intermediate phasor solution with an original phasor candidate solution by Cost(r)=min(|P_{w}(r)−Pₜₙ(r)|, |P_{f}(r)−Pₜₙ(r)|), wherein Pₜ is the phasor information of the pixel point in the intermediate phasor solution, Pₜₙ is the original phasor candidate solution, and r is the spatial position of the pixel point.

On the basis of the above embodiment, optionally, the apparatus further includes a phase wrapping processing module, which is configured to:
prior to performing phase conversion on the phasor candidate solutions for the purpose of enabling the difference between the correct solution and the inverse decomposition solution of the phasor candidate solutions to be within the set range, when phase wrapping exists in the phasor candidate solutions, perform phase unwrapping on the phasor candidate solutions by a second intermediate variable to obtain a second unwrapped phase; and
perform phase compression on the second unwrapped phase to compress the second unwrapped phase within a set range.

On the basis of the above embodiment, optionally, the first chemical component is water and the second chemical component is fat.

The chemical-shift-encoded imaging apparatus based on phase unwrapping provided by the embodiments of the present disclosure can perform the chemical-shift-encoded imaging method based on phase unwrapping provided by any of the embodiments of the present disclosure, with corresponding functional modules and advantageous effects for performing the method.

### Embodiment Four

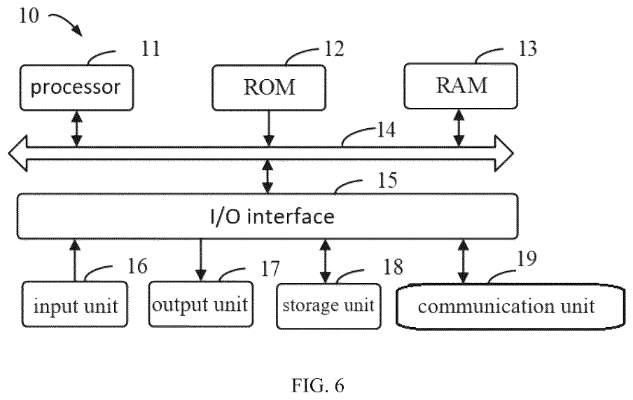

FIG. 6 is a structural schematic diagram of an electronic device according to Embodiment Four of the present disclosure. The electronic device 10 is intended to represent various forms of digital computers, such as laptops, desktops, workstations, personal digital assistants, servers, blade servers, mainframes, or other appropriate computers. The electronic device may also represent various forms of mobile devices, such as personal digital processing, cellular telephones, smart phones, wearable devices (e.g., helmets, glasses, watches, etc.), or other similar computing devices. The components shown herein, their connections, and their functions are meant to be examples only, and are not meant to limit implementations of the disclosures described and/or claimed in this document.

As shown in FIG. 6, the electronic device 10 includes at least one processor 11, and a memory communicatively connected with the at least one processor 11, such as a read only memory (ROM) 12, a random access memory (RAM) 13, etc., in which the memory stores a computer program executable by at least one processor, the processor 11 may perform various appropriate actions and processes in accordance with the computer program stored in the read only memory (ROM) 12 or loaded into the random access memory (RAM) 13 from the storage unit 18. In the RAM 13, various programs and data required for the operation of the electronic device 10 can also be stored. The processor 11, the ROM 12 and the RAM 13 are connected to each other by a bus 14. An input/output (I/O) interface 15 is also connected to the bus 14.

A number of components in the electronic device 10 are connected to the I/O interface 15, including: an input unit 16, such as a keyboard or mouse; an output unit 17, such as various types of displays or speakers or the like; a storage unit 18, such as a magnetic or optical disk, etc.; and a communication unit 19, such as a network card, a modem, or a wireless communication transceiver. The communication unit 19 allows the electronic device 10 to exchange information/data with other devices through computer networks such as the Internet and/or various telecommunication networks.

The processor 11 may be various general-purpose and/or special-purpose processing components having processing and computing capabilities. Some examples of the processor 11 include, but are not limited to, a central processing unit (CPU), a graphics processing unit (GPU), various specialized artificial intelligence (AI) computing chips, various processors running machine learning model algorithms, a digital signal processor (DSP), any suitable processor, controller or microcontroller, or the like. The processor 11 performs the various methods and processes described above, such as the chemical-shift-encoded imaging method based on phase unwrapping.

In some embodiments, the chemical-shift-encoded imaging method based on phase unwrapping may be implemented as a computer program tangibly embodied on a computer readable storage medium, such as storage unit 18. In some embodiments, part or all of the computer program may be loaded into and/or installed onto the electronic device 10 via the ROM 12 and/or the communication unit 19. When the computer program is loaded into the RAM 13 and executed by the processor 11, one or more steps of the PET parameter determination method described above may be performed. Alternatively, in other embodiments, the processor 11 may be configured to perform the chemical-shift-encoded imaging method based on phase unwrapping in any other suitable manner, e.g., by means of firmware.

Various implementations of the systems and techniques described above here can be realized in digital electronic circuit systems, integrated circuit systems, Field-Programmable Gate Arrays (FPGAs), Application-Specific Integrated Circuits (ASICs), Application-Specific Standard Products (ASSPs), Systems on Chip (SoCs), Complex Programmable Logic Devices (CPLDs), computer hardware, firmware, software, and/or combinations thereof. These various embodiments may include: being implemented in one or more computer programs that can be executed and/or interpreted on a programmable system including at least one programmable processor, which can be a dedicated or general-purpose programmable processor. This processor is capable of receiving data and instructions from a storage system, at least one input device, and at least one output device, and transmitting data and instructions to the storage system, the at least one input device, and the at least one output device.

Computer programs for carrying out the chemical-shift-encoded imaging method based on phase unwrapping of the present disclosure may be written in any combination of one or more programming languages. These computer programs may be provided to a processor of a general purpose computer, a special purpose computer, or other programmable data processing apparatuses, such that the computer programs, when executed by the processor, cause the functions/operations specified in the flowcharts and/or block diagrams to be implemented. The computer program may execute entirely on a machine or partially on a machine, partially on a machine as a stand-alone software package and partially on a remote machine or entirely on a remote machine or server.

### Embodiment Five

Embodiment Five of the present disclosure also provides a computer-readable storage medium storing computer instructions for causing a processor to perform a chemical-shift-encoded imaging method based on phase unwrapping, and the method includes:
an initial image is acquired, and phasor candidate solutions of the initial image are determined;
phase conversion is performed on the phasor candidate solutions for the purpose of enabling a difference between a correct solution and an inverse decomposition solution of the phasor candidate solutions to be within a set range, and on the basis of a phase unwrapping method, determination is performed to obtain an intermediate phasor solution;
a true phase of the intermediate phasor solution is determined, and the true phase is converted to a phasor candidate solution space to determine a target phasor solution; and
on the basis of the target phasor solution, a first chemical component signal and a second chemical component signal are determined, and on the basis of the first chemical component signal and/or the second chemical component signal, chemical-shift-encoded imaging is performed.

In the context of the present disclosure, a computer readable storage medium may be a tangible medium that can contain, or store a computer program for use by or in connection with an instruction execution system, apparatus, or device. A computer readable storage medium may include, but is not limited to, an electronic, magnetic, optical, electromagnetic, infrared, or semiconductor system, apparatus, or device, or any suitable combination of the foregoing. Alternatively, a computer readable storage medium may be a machine readable signal medium. A more specific example of the machine readable storage medium would include an electrical connection based on one or more wires, a portable computer diskette, a hard disk, a random access memory (RAM), a read-only memory (ROM), an erasable programmable read-only memory (EPROM or Flash memory), an optical fiber, a convenient compact disc read-only memory (CD-ROM), an optical storage device, a magnetic storage device, or any suitable combination of the foregoing.

To provide for interaction with a user, the systems and techniques described here can be implemented on an electronic device having a display device (e.g., a CRT (cathode ray tube) or LCD (liquid crystal display) monitor) for displaying information to the user; and a keyboard and a pointing device (e.g., a mouse or trackball) by which a user can provide input to an electronic device. Other kinds of devices can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The systems and techniques described here can be implemented in a computing system that includes back-end components (e.g., as a data server), or a computing system that includes a middleware component (e.g., an application server), or a computing system that includes a front-end component (e.g., a user computer having a graphical user interface or a Web browser through which a user can interact with an implementation of the systems and techniques described here), or a computing system that includes any combination of such back-end component, middleware, or front-end component. The components of the system can be interconnected by any form or medium of digital data communication (e.g., a communication network). Examples of the communication network include a local area network (LAN), a wide area network (WAN), a block chain network, and the Internet.

The computing system can include clients and servers. The client and server are generally remote from each other and typically interact through a communication network. The relationship of the client and server arises by virtue of computer programs running on the respective computers and having a client-server relationship to each other. The server may be a cloud server, also referred to as a cloud computing server or a cloud host, and is a host product in a cloud computing service architecture to solve the drawbacks of the conventional physical host and VPS services, which are difficult to manage and weak to scale.

It should be understood that steps may be reordered, added, or deleted using the various flow forms shown above. For example, the steps described in the present disclosure may be executed in parallel, sequentially, or in different orders, and are not limited herein as long as the desired results of the aspect of the present disclosure can be achieved.

The foregoing detailed implementations should not be construed as limiting the scope of the present disclosure. It should be understood by those skilled in the art that various modifications, combinations, sub-combinations and substitutions can occur depending on design requirements and other factors. It is intended that all such modifications, equivalents, modifications, and the like, which fall within the spirit and principles of the present disclosure, be included within the scope of the present disclosure.

What is claimed is:

1. A chemical-shift-encoded imaging method based on phase unwrapping, comprising:
acquiring an initial image, and determining phasor candidate solutions of the initial image;
performing phase conversion on the phasor candidate solutions for the purpose of enabling a difference between a correct solution and an inverse decomposition solution of the phasor candidate solutions to be within a set range, and on the basis of a phase unwrapping method, performing determination to obtain an intermediate phasor solution;
determining a true phase of the intermediate phasor solution, and converting the true phase to a phasor candidate solution space to determine a target phasor solution; and
on the basis of the target phasor solution, determining a first chemical component signal and a second chemical component signal, and on the basis of the first chemical component signal and/or the second chemical component signal, performing chemical-shift-encoded imaging.

2. The method according to claim 1, wherein performing phase conversion on the phasor candidate solutions for the purpose of enabling the difference between the correct solution and the inverse decomposition solution of the phasor candidate solutions to be within the set range comprises:
determining an intermediate variable corresponding to the correct solution and the inverse decomposition solution; and
performing phase conversion on the phasor candidate solutions based on a variable parameter of the intermediate variable such that a phase difference between the phasor candidate solutions is within a set range.

3. The method according to claim 1, wherein on the basis of the phase unwrapping method, performing determination to obtain the intermediate phasor solution comprises:
performing phase unwrapping on the intermediate variable to obtain a first unwrapped phase; and
matching the first unwrapped phase with an original phase candidate solution to obtain the intermediate phasor solution based on a matching result.

4. The method according to claim 1, wherein determining the true phase of the intermediate phasor solution comprises:
for a pixel point in the intermediate phasor solution, matching phasor information of the pixel point in the intermediate phasor solution with an original phasor candidate solution, determining target phasor information of the pixel point according to a matching result; and
determining the true phase according to the target phasor information of each pixel point.

5. The method according to claim 4, wherein matching the phasor information of the pixel point in the intermediate phasor solution with the original phasor candidate solution comprises:
matching phasor information of the pixel point in the intermediate phasor solution with an original phasor candidate solution by Cost(r)=min(|P_{w}(r)−Pₜₙ(r)|, |P_{f}(r)−Pₜₙ(r)), wherein Pₜ is the phasor information of the pixel point in the intermediate phasor solution, Pₜₙ is the original phasor candidate solution, and r is the spatial position of the pixel point.

6. The method according to claim 1, prior to performing phase conversion on the phasor candidate solutions for the purpose of enabling the difference between the correct solution and the inverse decomposition solution of the phasor candidate solutions to be within the set range, further comprising:
when phase wrapping exists in the phasor candidate solutions, performing phase unwrapping on the phasor candidate solutions by a second intermediate variable to obtain a second unwrapped phase; and
performing phase compression on the second unwrapped phase to compress the second unwrapped phase within a set range.

7. The method according to claim 1, wherein the first chemical component is water and the second chemical component is fat.

8. A chemical-shift-encoded imaging apparatus based on phase unwrapping, comprising:
a phasor candidate solution determining module, configured to acquire an initial image, and determine phasor candidate solutions of the initial image;
an intermediate phasor solution determining module, configured to perform phase conversion on the phasor candidate solutions for the purpose of enabling a difference between a correct solution and an inverse decomposition solution of the phasor candidate solutions to be within a set range, and on the basis of a phase unwrapping method, perform determination to obtain an intermediate phasor solution;
a target phasor solution determining module, configured to determine a true phase of the intermediate phasor solution, and convert the true phase to a phasor candidate solution space to determine a target phasor solution; and
a chemical-shift-encoded imaging module, configured to, on the basis of the target phasor solution, determine a first chemical component signal and a second chemical component signal, and on the basis of the first chemical component signal and/or the second chemical component signal, perform chemical-shift-encoded imaging.

9. An electronic device, comprising:
at least one processor; and
a memory communicatively connected with the at least one processor; wherein,
the memory stores a computer program executable by the at least one processor, the computer program being executed by the at least one processor to enable the at least one processor to perform the chemical-shift-encoded imaging method based on phase unwrapping according to claim 1.

10. A computer-readable storage medium having stored thereon computer instructions for causing a processor to implement the chemical-shift-encoded imaging method based on phase unwrapping according to claim 1 when executed.
